(19) United States
(12) Patent Application Publication
(10) Pub. No.: US 2015/0351223 A1
(43) Pub. Date: Dec. 3, 2015

(54) METAL-BASED MOUNTING BOARD AND MEMBER PROVIDED WITH METAL-BASED MOUNTING BOARD

(71) Applicant: SUMITOMO BAKELITE CO., LTD., Tokyo (JP)

(72) Inventors: Yoshihide Nii, Anjo-shi (JP); Toshio Komiyatani, Tokyo (JP); Yukiharu Yuzuriha, Tokyo (JP)

(73) Assignee: SUMITOMO BAKELITE CO., LTD., Tokyo (JP)

(21) Appl. No.: 14/728,125

(22) Filed: Jun. 2, 2015

(30) Foreign Application Priority Data
Jun. 3, 2014 (JP) 2014-114713

(51) Int. Cl. H05K 1/02; H05K 1/18

(52) U.S. Cl. CPC H05K 1/0209; H05K 1/181; H05K 2201/066

(57) ABSTRACT

The metal-based mounting board includes: a metal-based circuit board including a metal substrate having a first surface and a second surface, an insulating film provided on the first surface and a metal film provided on the insulating film; and an electronic component provided on the metal film of the metal-based circuit board. Within the metal substrate, a region which overlaps with a collection of a plurality of lines each having an angle of 45° or less with respect to a normal line of the metal-based mounting board, the lines each passing through a surface of the electronic component facing the metal film, is defined as a first region. A region other than the first region is defined as a second region. At least one groove is provided within the first region so as to surround the electronic component in a planar view of the metal-based mounting board.

### CROSS-REFERENCE TO RELATED APPLICATION

This application is based on and claims a priority from a Japanese Patent Application No. 2014-114713 filed on Jun. 3, 2014, which is hereby expressly incorporated by reference herein in its entirety.

### BACKGROUND OF THE INVENTION

1. Field of the invention

The present invention relates to a metal-based mounting board and a member provided with metal-based mounting board.

2. Description of the Related Art

Conventionally, inverter devices or power semiconductor devices each of which is formed by mounting semiconductor elements such as an insulated gate bipolar transistor (IGBT) and a diode, and electronic components such as a resistance and a condenser on a circuit board are known.

Since such devices include electronic components each having a large amount of heat generation, they are required to exhibit high heat radiation. In order to secure such high heat radiation, devices each having a structure in which a metal plate layer (a metal substrate) is bonded to an insulating resin adhesive layer (an insulating film) are being developed (see Patent document 1).

However, since linear expansion coefficients of the insulating film and the metal substrate are different from each other, warpage occurs in such a structure. This often causes problems such as heat radiation failure and connection failure of the electronic component.

Patent Document 1: JP-A 2011-216619

### SUMMARY OF THE INVENTION

Accordingly, it is an object of the present invention to provide a metal-based mounting board which has high heat radiation, and exhibits excellent connection reliability of an electronic component by effectively preventing occurrence of warpage caused by temperature change, and to provide a member provided with metal-based mounting board which has high heat radiation, and exhibits excellent connection reliability of an electronic component by effectively preventing occurrence of warpage caused by temperature change.

In order to achieve such an object, the present invention includes the following features (1) to (15).

(1) A metal-based mounting board comprising:

a metal-based circuit board including a metal substrate having a first surface and a second surface opposite to the first surface, an insulating film provided on the first surface of the metal substrate and a metal film provided on the insulating film; and

an electronic component provided on the metal film of the metal-based circuit board,

wherein in the case where within the metal substrate, a region which overlaps with a collection of a plurality of lines each having an angle of 45° or less with respect to a normal line of the metal-based mounting board, the lines each passing through a surface of the electronic component facing the metal film, is defined as a first region, and a region other than the first region is defined as a second region, at least one groove is provided within the first region so as to surround the electronic component in a planar view of the metal-based mounting board.

(2) The metal-based mounting board according to the above feature (1), wherein the electronic component includes at least one type of an insulated gate bipolor transistor, a field effect transistor and a transformer.

(3) The metal-based mounting board according to the above feature (1) or (2), wherein the metal substrate is formed of aluminum or an aluminum alloy.

(4) The metal-based mounting board according to any one of the above features (1) to (3), wherein the groove is provided on the second surface of the metal substrate.

(5) The metal-based mounting board according to any one of the above features (1) to (4), wherein a width of the groove is in the range of 0.025 to 5 mm.

(6) The metal-based mounting board according to any one of the above features (1) to (5), wherein a depth of the groove is in the range of 0.10 to 5 mm.

(7) The metal-based mounting board according to any one of the above features (1) to (6), wherein a thickness of the metal substrate is in the range of 0.8 to 7.0 mm.

(8) The metal-based mounting board according to any one of the above features (1) to (7), wherein in the case where a depth of the groove is defined as D [mm] and a thickness of the metal substrate is defined as T [mm], D and T satisfy a relationship of 0.20≦D/T≦0.95.

(9) The metal-based mounting board according to any one of the above features (1) to (8), wherein a thickness of the metal film is in the range of 10 to 500 μm.

(10) The metal-based mounting board according to any one of the above features (1) to (9), wherein a thickness of the insulating film is in the range of 40 to 300 μm.

(11) The metal-based mounting board according to any one of the above features (1) to (10), wherein in the case where in the second surface of the metal substrate, an area occupied by the first region is defined as S₁ [mm²] and an area occupied by the second region is defined as S₂ [mm²], S₁ and S₂ satisfy a relationship of 0.50≦S₁/S₂≦4.0.

(12) The metal-based mounting board according to any one of the above features (1) to (11), wherein in the case where in the second surface of the metal substrate, an area occupied by the first region is defined as S₁ [mm²] and an area occupied by the groove is defined as S_{G} [mm²], S₁ and S_{G} satisfy a relationship of 0.03≦S_{G}/S₁≦0.70.

(13) The metal-based mounting board according to any one of the above features (1) to (12), wherein the at least one groove includes a plurality of the grooves intersecting with each other.

(14) A member provided with metal-based mounting board comprising:

a cooler; and

the metal-based mounting board according to any one of the features (1) to (13) provided on the cooler.

(15) The member provided with metal-based mounting board according to the above feature (14), wherein the cooler is a housing of a motor.

### Effect of the Invention

According to the present invention, it is possible to provide a metal-based mounting board which has high heat radiation, and exhibits excellent connection reliability of an electronic component by effectively preventing occurrence of warpage caused by temperature change, and to provide a member provided with metal-based mounting board which has high heat radiation, and exhibits excellent connection reliability of an electronic component by effectively preventing occurrence of warpage caused by temperature change.

### BRIEF DESCRIPTION OF THE DRAWINGS

FIG. 1 is a cross-sectional view schematically showing a preferred embodiment of a metal-based mounting board according to the present invention.

FIG. 2 is a bottom view schematically showing the preferred embodiment of the metal-based mounting board according to the present invention.

FIG. 3 is a cross-sectional view schematically showing a preferred embodiment of a member provided with metal-based mounting board according to the present invention.

FIG. 4 is a perspective view showing a preferred embodiment of a motor with board in which the metal-based mounting board (the member provided with metal-based mounting board) according to the present invention is used.

### DETAILED DESCRIPTION OF THE INVENTION

Hereinbelow, description will be made on a metal-based mounting board and a member provided with metal-based mounting board according to the present invention in detail based on preferred embodiments shown in the attached drawings.

<<Metal-Based Mounting Board>>

First, the metal-based mounting board according to the present invention will be described.

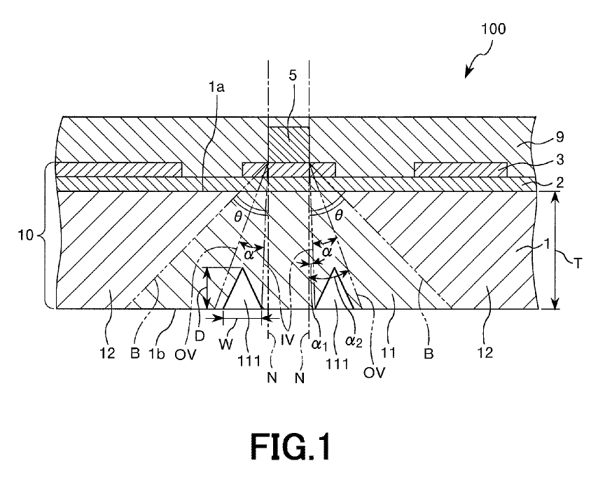

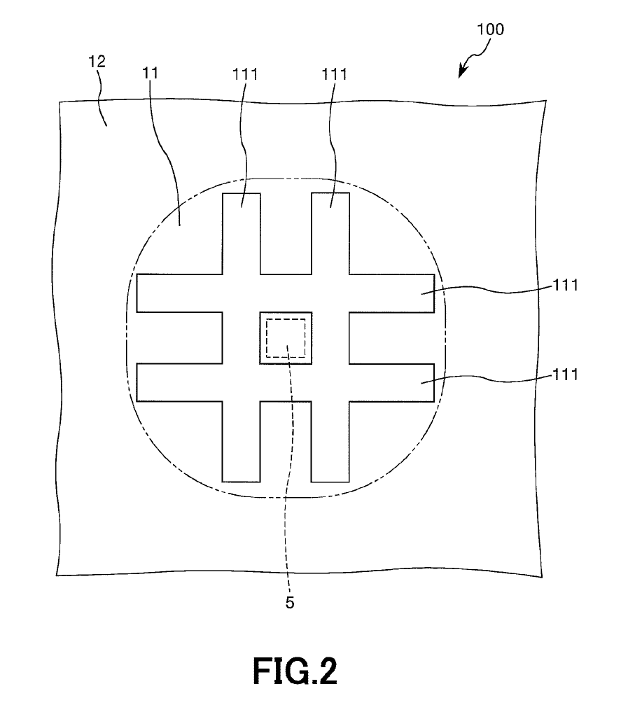

FIG. 1 is a cross-sectional view schematically showing a preferred embodiment of the metal-based mounting board according to the present invention, and FIG. 2 is a bottom view schematically showing the preferred embodiment of the metal-based mounting board according to the present invention.

In this regard, in the following description, the upper side in FIG. 1 is referred to as the “upper”, the lower side therein is referred to as the “lower”, the right side therein is referred to as the “right”, and the left side therein is referred to as the “left”. Further, the drawings referred in this specification exaggeratingly show a part of components, and do not correctly reflect an actual size ratio and the like thereof.

A metal-based mounting board (an electronic device) 100 includes a metal-based circuit board 10, and an electronic component 5 provided on the metal-based circuit board 10.

<<Metal-Based Circuit Board>>

The metal-based circuit board 10 includes a metal substrate 1 having an upper surface (a first surface) 1a and a lower surface (a second surface opposite to the first surface) 1b, an insulating film 2 provided on the upper surface 1a of the metal substrate 1, and a metal film 3 provided on the insulating film 2.

<Metal Substrate>

The metal substrate 1 has a function of supporting the insulating film 2 and the metal film 3.

The metal substrate 1 is constituted from a material containing a metal material. The metal material generally has excellent heat transfer. Therefore, the metal-based circuit board 10 including such a metal substrate 1 can exhibit superior heat radiation as a whole.

Examples of the metal material constituting the metal substrate 1 include, but are not especially limited to, metal simple substances such as aluminum and copper, alloys each containing at least one type selected therefrom, and the like. Among them, aluminum or an aluminum alloy is preferable as the metal material from a comprehensive viewpoint based on excellent heat transfer (heat radiation), mechanical strength, chemical stability, a balance of a linear expansion coefficient and heat transfer, and the like.

A thickness of the metal substrate 1 (a thickness of a portion of the metal substrate 1 where grooves 111, which will be described in detail, are not provided) is not limited to a specific value, but is preferably in the range of 0.8 to 7.0 mm, and more preferably in the range of 1.0 to 5.0 mm.

If the thickness of the metal substrate 1 is a value falling within the above range, it is possible to make properties such as the heat radiation and the mechanical strength of the metal substrate 1 especially excellent, and to especially improve workability such as a bending property of the metal substrate 1.

In contrast, if the thickness of the metal substrate 1 is less than the above lower limit value, a falling tendency in the heat radiation and the mechanical strength of the metal substrate 1 occurs.

On the other hand, if the thickness of the metal substrate 1 exceeds the above upper limit value, a falling tendency in the workability such as the bending property of the metal substrate 1 occurs.

A plurality of linear grooves 111 each opening at the lower surface lb are provided (formed) on the metal substrate 1.

Since this allows a surface area of the metal substrate 1 to become larger than that of a metal substrate having no groove 111, it is possible to make the heat radiation of the metal substrate 1 excellent. Further, existence of the grooves 111 also makes it possible to prevent occurrence of warpage of the metal-based circuit board 10 caused by temperature change (warpage caused by a difference between linear expansion coefficients of the respective components).

As a result, even if the metal-based mounting board (the electronic device) 100 is placed, for example, under the environment of rapid heating/cooling, it becomes possible to suppress failures such as cracks from being generated in a brazing material bonded portion through which the electronic component 5 and the metal-based circuit board 10 are bonded together or near it. In other words, it is possible to improve a heat cycle property of the metal-based circuit board 10.

In particular, since the grooves 111 are provided on the lower surface (the surface on the opposite side of the insulating film 2) lb of the metal substrate 1, it is possible to make a heat radiation efficiency through the metal substrate 1 especially excellent, to thereby exhibit the above mentioned effects more remarkably.

Further, the grooves 111 are provided at a position satisfying a predetermined relationship with respect to the electronic component 5.

Specifically, within the metal substrate 1, a region which overlaps with a collection of a plurality of lines (virtual lines) each having an angle of 45° or less with respect to a normal line of the metal-based mounting board 100 (the metal-based circuit board 10), the lines each passing through a lower surface (a surface facing the metal film 3) of the electronic component 5 is defined as a first region 11, and a region other than the first region 11 is defined as a second region 12, the grooves 111 are provided within the first region 11.

Here, as shown in FIGS. 1 and 2, a cross-section of the first region 11 along a planar direction thereof increases toward the lower surface 1b of the metal substrate 1 from the upper surface 1a thereof. In other words, the first region 11 includes a columnar central portion overlapping with the electronic component 5 in a planar view of the metal-based mounting board 100, and a peripheral portion surrounding the central portion and having a cross-section along a planar direction thereof increasing (gradually increasing) toward the lower surface lb of the metal substrate 1 from the upper surface la thereof.

Then, an inclination angle of such a peripheral portion, that is, an angle “θ” formed by a boundary B (indicated by two-dot chain line) between the first region 11 and the second region 12 and a normal line N (indicated by dot-and-dash line) of the metal-based mounting board 100 passing through an edge (an edge on the side of the metal film 3) of the electronic component 5 in FIG. 1 is 45°. In this regard, the normal line N of the metal-based mounting board 100 for defining the angle “θ” intersects with an extended line of the boundary B at an intersection point thereof with the lower surface of the electronic component 5.

Further, in this embodiment, a planar shape of the electronic component 5 is a square shape. The cross-section of the metal-based mounting board 100 along the thickness direction thereof shown in FIG. 1 corresponds to the cross-section obtained by cutting the metal-based mounting board 100 along a line parallel to one side or a diagonal line of the planar shape of the electronic component 5 (the square shape).

By providing the grooves 111 at the position satisfying the predetermined relationship with respect to the electronic component 5 in this way, it is possible to make a heat radiation effect of the metal substrate 1 especially excellent. Further, it is also possible to more effectively prevent the occurrence of the warpage of the metal-based circuit board 10 caused by the temperature change, to thereby especially improve connection reliability of the electronic component 5.

It is considered that such effects are obtained by the following reasons.

Namely, heat generated by the electronic component 5 is transferred to the metal substrate 1 through the metal film 3 and the insulating film 2 by heat transfer. In this regard, since thicknesses of the metal film 3 and the insulating film 2 are sufficiently thin, the heat generated by the electronic component 5 is transferred to the metal substrate 1, while being hardly diffused in a planar direction of the metal film 3 and the insulating film 2. Heat transfer inside the metal substrate 1 does not isotropically progress, but preferentially progresses along a thickness direction thereof, especially, the above mentioned first region 11.

Therefore, by providing the grooves 111 within the first region 11, it is possible to make a surface area of a region of the metal substrate 1 where the heat is preferentially transferred (the first region 11) larger, to thereby increase the heat radiation of the metal substrate 1 as a whole. Further, by providing the grooves 111 within the first region 11, it is possible to make the heat radiation of the metal substrate 1 as a whole especially excellent without providing a groove(s) within the second region 12. In other words, by selectively providing the grooves within a predetermined region (the first region 11), it is possible to make the heat radiation of the metal substrate 1 excellent, and to improve the mechanical strength and shape stability of the metal substrate 1 (the metal-based mounting board 100, the metal-based circuit board 10). This makes it possible to more effectively prevent the occurrence of the warpage of the metal-based circuit board 10 caused by the temperature change, to thereby especially improve the connection reliability of the electronic component 5.

Each groove 111 has only to exist within the first region 11 as described above, but preferably exists within a range having an angle α, which is separated from the second region 12 at a predetermined distance, as shown in FIG. 1. In this regard, an angle α₁ formed by an inside virtual line IV defining this range and the normal line N of the metal-based mounting board 100 (the metal-based circuit board 10) is preferably 0° or more. On the other hand, an angle α₂ formed by an outside virtual line OV defining this range and the normal line N of the metal-based mounting board 100 (the metal-based circuit board 10) is preferably 40° or less, and more preferably 35° or less.

This makes it possible to exhibit the above mentioned effects more remarkably.

In the case where in the lower surface lb of the metal substrate 1, an area occupied by the first region 11 is defined as S₁ [mm²] and an area occupied by the second region 12 is defined as S₂ [mm²], S₁ and S₂ preferably satisfy a relationship of 0.50≦S₁/S₂≦4.0, and more preferably satisfy a relationship of 1.0≦S₁/S₂≦2.0

By satisfying such a relationship, it is possible to make the heat radiation of the metal substrate 1 especially excellent, while sufficiently increasing a mounting density of the electronic components 5.

In the configuration shown in FIGS. 1 and 2, the plurality of grooves 111 are provided.

This allows the surface area of the metal substrate 1 to become larger, to thereby make the heat radiation of the metal substrate 1 especially excellent. Further, this also makes it possible to more effectively prevent the occurrence of the warpage of the metal-based circuit board 10.

A width (maximum width) of each groove 111 indicated as “W” in FIG. 1 is preferably in the range of 0.025 to 5 mm, and more preferably in the range of 0.05 to 4 mm.

This makes it possible to sufficiently improve the mechanical strength of the metal-based circuit board 10, and to make the heat radiation of the metal substrate 1 further excellent, and to thereby more effectively prevent the occurrence of the warpage of the metal-based circuit board 10.

In contrast, if the width of each groove 111 is less than the above lower limit value, it becomes difficult to make the surface area of the metal substrate 1 sufficiently large, and thus there is a possibility that the heat radiation of the metal substrate 1 decreases.

On the other hand, if the width of each groove 111 exceeds the above upper limit value, there is a possibility that it becomes difficult to sufficiently improve the mechanical strength of the metal-based mounting board 100 (the metal-based circuit board 10).

In the metal-based circuit board 10 shown in FIG. 1, each groove 111 is a bottomed groove with a bottom part by being not passed through the metal substrate 1.

This makes it possible to especially improve the mechanical strength of the metal-based mounting board 100 (the metal-based circuit board 10). Further, this also makes it possible to make heat transfer of both regions existing through each groove 111 in a bottom view of the metal-based mounting board 100 (the metal-based circuit board 10) especially large, to thereby make the heat radiation of the metal-based mounting board 100 (the metal-based circuit board 10) as a whole especially excellent.

A depth (maximum depth) of each groove 111 indicated as “D” in FIG. 1 is preferably in the range of 0.10 to 5 mm, and more preferably in the range of 0.40 to 4 mm.

In this case, the metal-based circuit board 10 can exhibit the mechanical strength and a warpage prevention effect in a higher level.

In contrast, if the depth of each groove 111 is less than the above lower limit value, it becomes difficult to make the surface area of the metal substrate 1 sufficiently large, and thus there is a possibility that the heat radiation of the metal substrate 1 decreases.

On the other hand, if the depth of each groove 111 exceeds the above upper limit value, there is a possibility that it becomes difficult to sufficiently improve the mechanical strength of the metal-based mounting board 100 (the metal-based circuit board 10).

In this regard, a cross-sectional shape of each groove 111 is not limited to a triangular shape of which a top faces the upper surface la of the metal substrate 1 as shown in FIG. 1, but may be any shapes such as a semicircle shape.

In the case where the depth of each groove 111 is defined as D [mm] and the thickness of the metal substrate 1 is defined as T [mm], D and T preferably satisfy a relationship of 0.20≦D/T≦0.95, more preferably satisfy a relationship of 0.25≦D/T≦0.95, and even more preferably satisfy a relationship of 0.40≦D/T≦0.80.

In this case, the metal-based circuit board 10 can exhibit the mechanical strength and the warpage prevention effect in the higher level.

In contrast, if the D/T value is less than the above lower limit value, it becomes difficult to make the surface area of the metal substrate 1 sufficiently large, and thus there is a possibility that the heat radiation of the metal substrate 1 decreases.

On the other hand, if the D/T value exceeds the above upper limit value, there is a possibility that it becomes difficult to sufficiently improve the mechanical strength of the metal-based mounting board 100 (the metal-based circuit board 10).

In the metal-based circuit board 10 shown in FIG. 1 as described above, each groove 111 is the bottomed groove with the bottom part by being not passed through the metal substrate 1. However, the grooves 111 provided on the metal substrate 1 may include a through-groove(s) passing through the metal substrate 1 along a thickness direction thereof.

A length of each groove 111 is not limited to a specific value, but is preferably in the range of 10 to 90% of a length of the metal substrate 1 along an extending direction of each groove 111, and more preferably in the range of 20 to 80% thereof.

This makes it possible to sufficiently improve the mechanical strength of the metal-based circuit board 10, and to make the heat radiation of the metal substrate 1 further excellent, to thereby more effectively prevent the occurrence of the warpage of the metal-based circuit board 10.

In contrast, if the length of each groove 111 is less than the above lower limit value, it becomes difficult to make the surface area of the metal substrate 1 sufficiently large, and thus there is a possibility that the heat radiation of the metal substrate 1 decreases.

On the other hand, if the length of each groove 111 exceeds the above upper limit value, there is a possibility that it becomes difficult to sufficiently improve the mechanical strength of the metal-based mounting board 100 (the metal-based circuit board 10).

A gap (pitch) between the adjacent grooves 111 is not limited to a specific value, but is preferably in the range of 0.2 to 40 mm, and more preferably in the range of 0.5 to 10 mm.

This makes it possible to make the heat radiation of the metal substrate 1 especially excellent, to therby more effectively prevent the occurrence of the warpage of the metal-based circuit board 10 caused by the temperature change. Further, this also makes it possible to especially improve the mechanical strength of the metal-based circuit board 10.

In contrast, if the gap between the adjacent grooves 111 is less than the lower limit value, there is a possibility that it becomes difficult to sufficiently improve the mechanical strength of the metal-based mounting board 100 (the metal-based circuit board 10).

On the other hand, if the gap between the adjacent grooves 111 exceeds the upper limit value, it becomes difficult to make the surface area of the metal substrate 1 sufficiently large, and thus there is a possibility that the heat radiation of the metal substrate 1 decreases.

In the case where in the lower surface lb of the metal substrate 1, the area occupied by the first region 12 is defined as S₁ [mm²] and an area occupied by the grooves 111 is defined as S_{G} [mm²], S₁ and S_{G} preferably satisfy a relationship of 0.03≦S_{G}/S₁≦0.70, and more preferably satisfy a relationship of 0.05≦S_{G}/S₁≦0.40.

In this case, the metal-based circuit board 10 can exhibit the mechanical strength and the warpage prevention effect in the higher level.

In contrast, if the S_{G}/S₂ value is less than the above lower limit value, it becomes difficult to make the surface area of the metal substrate 1 sufficiently large, and thus there is a possibility that the heat radiation of the metal substrate 1 decreases.

On the other hand, if the S_{G}/S₂ value exceeds the above upper limit value, there is a possibility that it becomes difficult to sufficiently improve the mechanical strength of the metal-based mounting board 100 (the metal-based circuit board 10).

In the present invention, the plurality of grooves 111 are provided so as to surround the electronic component 5 in the bottom view (the planar view) of the metal-based mounting board 100. In particular, in this embodiment, the plurality of grooves 111 are provided so as to be at right angles to each other. This makes it possible to make the heat radiation efficiency of the metal substrate 1 especially excellent, while sufficiently maintaining the mechanical strength of the metal substrate 1, to thereby more effectively prevent the occurrence of the warpage of the metal-based circuit board 10.

<Insulating Film>

The insulating film 2 is a film having an insulating property, and has functions of preventing a short circuit between a circuit formed within the metal film 3 and the metal substrate 1 and bonding the metal film 3 to the metal substrate 1.

A thickness of the insulating film 2 is not limited to a specific value, but is preferably in the range of 40 to 300 μm.

If the thickness of the insulating film 2 is a value falling within the above range, it is possible for the insulating film 2 to effectively transfer the heat applied from the upper side thereof to the metal substrate 1. This makes it possible to make the heat radiation of the metal-based circuit board 10 as a whole especially excellent, and to effectively absorb generation of heat stress due to a difference between thermal expansion coefficients of the metal substrate 1 and the insulating film 2.

Further, it is also possible to make the insulating property of the insulating film 2 specifically excellent. Furthermore, it is also possible to effectively prevent the heat from being diffused within the insulating film 2 in a planar direction thereof, to thereby exhibit the effects obtained by providing the grooves 111 more remarkably.

In contrast, if the thickness of the insulating film 2 is less than the above lower limit value, there is a possibility that it becomes difficult to sufficiently absorb the generation of the heat stress between the metal substrate 1 and the insulating film 2 depending on the difference between the thermal expansion coefficients of the metal substrate 1 and the insulating film 2. Further, there is a possibility that it becomes difficult to make the insulating property of the insulating film 2 sufficiently excellent.

Further, if the thickness of the insulating film 2 exceeds the above upper limit value, a falling tendency in the heat radiation of the metal-based circuit board 10 as a whole occurs.

The insulating film 2 has only to have the insulating property as a whole, but is generally constituted from an insulating material having a high insulating property.

Examples of the constituent material of the insulating film 2 include various kinds of insulating resin materials, various kinds of ceramics materials, and the like.

Examples of the insulating material constituting the insulating film 2 include an epoxy resin, a phenoxy resin, and the like.

As the epoxy resin, an epoxy resin having at least one of an aromatic ring structure and an alicyclic structure (an alicyclic carbon ring structure) can be appropriately used.

By using such an epoxy resin, it is possible to increse a glass transition temperature of the insulating film 2, and to further improve the heat transfer of the insulating film 2.

Examples of the epoxy resin having the aromatic ring structure or the alicyclic structure include: a bisphenol type epoxy resin such as bisphenol A type epoxy resin, bisphenol F type epoxy resin, bisphenol S type epoxy resin, bisphenol E type epoxy resin, bisphenol M type epoxy resin, bisphenol P type epoxy resin, or bisphenol Z type epoxy resin; a novolac type epoxy resin such as phenol novolac type epoxy resin, cresol novolac type epoxy resin, or tetraphenol group-ethane type novolac type epoxy resin; a biphenyl type epoxy resin; an aryl alkylene type epoxy resin such as a phenol aralkyl type epoxy resin having a biphenylene skeleton; a naphthalene type epoxy resin; and the like. In this regard, one type of them can be used alone, or two or more of them can be used in combination as such an epoxy resin.

In the case where the insulating film 2 is constituted from a material containing the phenoxy resin, it is possible to improve bending resistance of the insulating film 2.

Further, by containing the phenoxy resin, it becomes possible to decrease an elastic modulus of the insulating film 2. This makes it possible to improve a stress relief force of the metal-based circuit board 10.

Examples of the phenoxy resin include a phenoxy resin having a bisphenol skeleton, a phenoxy resin having a naphthalene skeleton, a phenoxy resin having an anthracene skeleton, a phenoxy resin having a biphenyl skeleton, and the like. Further, a phenoxy resin having a plurality of types of these skeletons can also be used.

Examples of the ceramics material constituting the insulating film 2 include alumina and the like.

The insulating film 2 may include the ceramics material and the insulating resin material. For example, the insulating film 2 may be constituted from a material in which particles each composed of the ceramics material are dispersed in the insulating resin material.

The insulating film 2 may have an uniform composition at various regions thereof, or different compositions at a part of the regions. For example, the insulating film 2 may be a laminated body having a plurality of layers with different compositions, or may be constituted from a material of which a composition changes along the thickness direction thereof in an inclined manner.

<Metal Film>

The metal film 3 is a portion forming a circuit of the metal-based circuit board 10.

The metal film (a circuit pattern) 3 is formed of metals such as copper, aluminum, nickel, iron and tin. In this regard, the metal film 3 may contain two or more types of the metals.

A thickness of the metal film 3 is not limited to a specific value, but is preferably in the range of 10 to 500 μm, and more preferably in the range of 20 to 300 μm.

If the thickness of the metal film 3 is a value falling within the above range, it is possible to especially improve durability of the metal-based mounting board 100. Further, it is also possible to make loss of electric current in the metal film 3 smaller, to thereby more stably pass larger electric current through the metal film 3. Furthermore, it is also possible to effectively prevent diffusion of the heat in a planar direction of the metal film 3, to thereby exhibit the effects obtained by providing the above mentioned grooves 111 more remarkably.

In this regard, additional layers such as a bonding layer may be provided between the insulating film 2 and the metal film 3.

The metal film 3 may have an uniform composition at various regions thereof, or different compositions at a part of the regions. For example, the metal film 3 may be a laminated body having a plurality of layers with different compositions, or may be constituted from a material of which a composition changes along the thickness direction thereof in an inclined manner.

<<Electronic Component>>

The electronic component 5 is connected to the metal film 3 of the above mentioned metal-based circuit board 10. In this way, an electronic circuit has been completed.

Examples of the electronic component 5 include: an IC chip such as a microcomputer; a semiconductor element such as an insulated gate bipolar transistor, a field effect transistor, a transformer or a diode; a resistance; a condenser; and the like.

It is preferred that the metal-based mounting board 100 is, especially, provided with at least one type selected from the insulated gate bipolar transistor, the field effect transistor and the transformer among them as the electronic component 5.

These are electronic components each having a large amount of heat generation and called a power device. Therefore, a metal-based mounting board 100 provided with such an electronic component is required to have higher heat radiation, but easily produced the problem described in the related art. On the other hand, in the present invention, even in the case of providing such an electronic component, it is possible to reliably prevent the above mentioned problem from being produced. In other words, in the case where the metal-based mounting board 100 is provided with such an electronic component, the effects of the present invention can be more remarkably exhibited.

<Sealing Material>

In the configuration shown in FIG. 1, a sealing material 9 is provided on the side (the upper side in FIG. 1) of a surface of the metal-based circuit board 10 on which the circuit (the metal film 3) is formed, to thereby cover the metal film 3 and the electronic component 5.

This makes it possible to make moisture resistance, chemical resistance and the like of the metal-based mounting board 100 especially excellent, to thereby improve the reliability of the metal-based mounting board 100.

A thickness of the sealing material 9 is not limited to a specific value, but is preferably in the range of 200 μm to 3 mm.

If the thickness of the sealing material 9 is a value falling within the above range, it is possible to reliably cover the metal film 3 and the electronic component 5, while effectively preventing the metal-based mounting board 100 from thickening. This makes it possible to more reliably exhibit the above effects.

In contrast, if the thickness of the sealing material 9 is less than the above lower limit value, it becomes difficult to stably cover the metal film 3 and the electronic component 5 for a long period of time, and thus there is a possibility that the above effects cannot be sufficiently exhibited.

On the other hand, if the thickness of the sealing material 9 exceeds the above upper limit value, there is a case that the metal-based mounting board 100 becomes thickened.

Examples of a constituent material of the sealing material 9 include various kinds of insulating resin materials, various kinds of ceramics materials, and the like.

Examples of the insulating material constituting the sealing material 9 include an epoxy resin, a phenoxy resin, and the like.

As the epoxy resin, an epoxy resin having at least one of an aromatic ring structure and an alicyclic structure (an alicyclic carbon ring structure) can be appropriately used.

By using such an epoxy resin, it is possible to increse a glass transition temperature of the sealing material 9, and to further improve heat transfer of the sealing material 9.

Examples of the epoxy resin having the aromatic ring structure or the alicyclic structure include: a bisphenol type epoxy resin such as bisphenol A type epoxy resin, bisphenol F type epoxy resin, bisphenol S type epoxy resin, bisphenol E type epoxy resin, bisphenol M type epoxy resin, bisphenol P type epoxy resin, or bisphenol Z type epoxy resin; a novolac type epoxy resin such as phenol novolac type epoxy resin, cresol novolac type epoxy resin, or tetraphenol group-ethane type novolac type epoxy resin; a biphenyl type epoxy resin; an aryl alkylene type epoxy resin such as a phenol aralkyl type epoxy resin having a biphenylene skeleton; a naphthalene type epoxy resin; and the like. In this regard, one type of them can be used alone, or two or more of them can be used in combination as such an epoxy resin.

In the case where the sealing material 9 is constituted from a material containing the phenoxy resin, it is possible to improve bending resistance of the sealing material 9.

Further, by containing the phenoxy resin, it becomes possible to decrease an elastic modulus of the sealing material 9. This makes it possible to improve the stress relief force of the metal-based circuit board 10.

Examples of the phenoxy resin include a phenoxy resin having a bisphenol skeleton, a phenoxy resin having a naphthalene skeleton, a phenoxy resin having an anthracene skeleton, a phenoxy resin having a biphenyl skeleton, and the like. Further, a phenoxy resin having a plurality of types of these skeletons can also be used.

Examples of the ceramics material constituting the sealing material 9 include alumina and the like.

The sealing material 9 may include the ceramics material and the insulating resin material. For example, the sealing material 9 may be constituted from a material in which particles each composed of the ceramics material are dispersed in the insulating resin material.

The sealing material 9 may have an uniform composition at various regions thereof, or different compositions at a part of the regions. For example, the sealing material 9 may be a laminated body having a plurality of layers with different compositions, or may be constituted from a material of which a composition changes along a thickness direction thereof in an inclined manner.

The metal-based mounting board 100 may be used in any devices. Examples of such devices include semiconductor devices such as a power semiconductor device, a LED illumination and an inverter device. Although such semiconductor devices have generally large amounts of heat generation, their heat can be efficiently radiated according to the present invention. Therefore, the present invention can be appropriately used in such semiconductor devices.

Here, the inverter device is a device electrically generating an alternating current from a direct current (having a reverse changing feature). Further, the power semiconductor device has properties such as a high pressure-resistant property, a high current property and a high speed and frequency property as compared with an usual semiconductor element, and is generally called a power device. Examples of such a power semiconductor device include a rectifier diode, a power transistor, a power MOSFET, an insulated gate bipolar transistor (IGBT), a thyristor, a gate turn-off thyristor (GTO), a triac, and the like.

<<Member Provided with Metal-based Mounting Board>>

Next, a member provided with metal-based mounting board according to the present invention will be described.

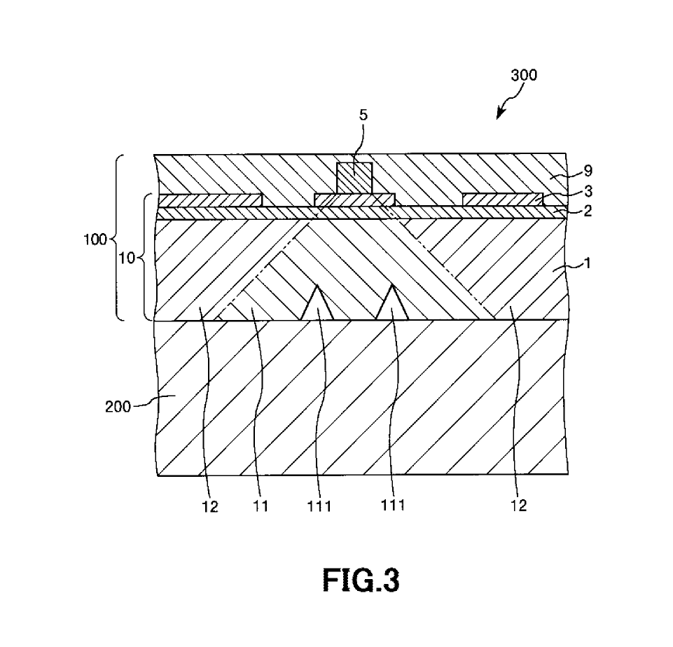

FIG. 3 is a cross-sectional view schematically showing a preferred embodiment of the member provided with metal-based mounting board according to the present invention.

As shown in FIG. 3, a member provided with metal-based mounting board 300 includes a cooler 200, and the metal-based mounting board 100 provided so as to make contact with the cooler 200.

By including such a configuration, a part of heat to be radiated can be transferred to the cooler 200 from the metal substrate 1. Therefore, it is possible to make a heat radiation efficiency of the member provided with metal-based mounting board 300 as a whole especially excellent. This makes it possible to more effectively prevent occurrence of warpage of the metal-based mounting board 100 caused by temperature change, to thereby especially improve the connection reliability of the electronic component 5.

The cooler 200 is usually formed of a material having high heat transfer.

Examples of the constituent material of the cooler 200 include metal simple substances such as aluminum and copper, alloys each containing at least one type selected therefrom, and the like. Among them, aluminum or an aluminum alloy is preferable as the constituent material of the cooler 200 from a comprehensive viewpoint based on excellent heat transfer (heat radiation), mechanical strength, chemical stability, a balance of linear expansion coefficient and heat transfer, and the like.

In the configuration shown in FIG. 3, the cooler 200 is of a plate shape, but the shape of the cooler 200 is not limited thereto. For example, the cooler 200 may have fins.

<<Motor with Board>>

Next, description will be made on a motor with board as one concrete example of the member provided with metal-based mounting board according to the present invention.

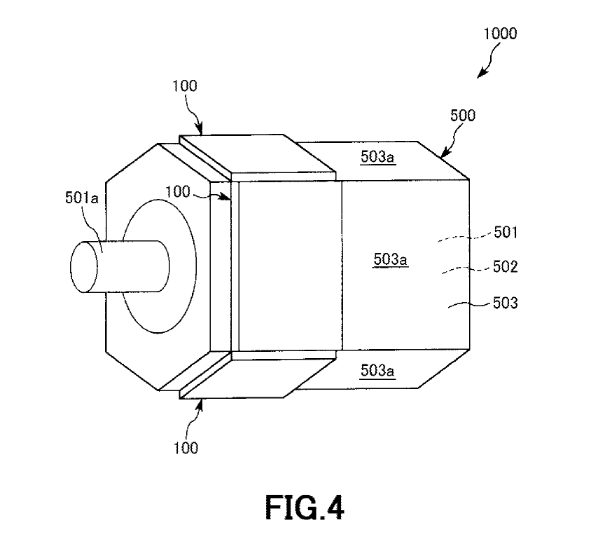

FIG. 4 is a perspective view showing a preferred embodiment of the motor with board in which the metal-based mounting board (the member provided with metal-based mounting board) according to the present invention is used.

A motor with board 1000 shown in FIG. 4 is an electromotive integrated motor including a motor 500 and three metal-based mounting boards 100 provided on an outer peripheral portion of the motor 500.

The motor 500 is a SR motor with a three-phase including a U phase, a V phase and a W phase. The SR motor is provided in an electric car in recent years, and is used, for example, as a driving source.

As shown in FIG. 4, the motor 500 includes a rotor 501 to which a shaft 501a is connected, a stator 502 which rotatably houses and supports the rotor 501, and a housing 503 which houses the stator 502.

A whole shape of the housing 503 (the motor 500) is a hexagonal columnar shape. In other words, an outer peripheral portion of the housing 503 is of a hexagonal shape in which normal line directions of the adjacent side surfaces 503a are different from each other.

The three metal-based mounting boards 100 are control boards for controlling operation (driving) of the motor 500. Each metal-based mounting board 100 serves as an inverter for the U phase, an inverter for the V phase or an inverter for the W phase.

As described above, each metal-based mounting board 100 includes the metal-based circuit board 10 and the electronic component 5 provided on the metal-based circuit board 10.

In this embodiment, each metal-based circuit board 10 is a circuit board for mounting an output inverter circuit for any one phase of the 3 phases (the U phase, the V phase and the W phase).

As described above, each metal-based circuit board 10 includes the metal substrate 1, the insulating film 2 provided on the upper surface la of the metal substrate 1, and the metal film 3 provided on the insulating film 2.

The grooves 111 each satisfying the above mentioned condition are provided on the metal substrate 1, and the metal substrate 1 makes contact with the housing 503 at the lower surface (the surface on which the grooves 111 are provided) lb thereof. In other words, the housing 503 serves as the cooler, and a portion including the metal-based mounting boards 100 and the housing 503 of the motor with board 1000 serves as the member provided with metal-based mounting board.

Such a configuration is especially advantageous in that a cooling efficiency of the motor with board (a device provided with the metal-based mounting board(s) 100) 1000 can be especially improved, and a size of the motor with board 1000 can be made smaller.

Hereinabove the preferred embodiments of the present invention have been described, but the present invention is not limited thereto. The present invention includes modification, improvement and the like within the scope capable of achieving the purposes of the present invention.

For example, each groove is of the linear shape in the above mentioned embodiment, but may be of a curved shape (including a spiral pattern, a concentric pattern or the like).

Further, the plurality of grooves are provided on the metal substrate in the above mentioned embodiment, but at least one groove has only to be provided thereon.

Furthermore, the grooves are provided on the lower surface (the surface on the opposite side of the insulating film) of the metal substrate in the above mentioned embodiment, but may be provided on the upper surface (the surface on the side of the insulating film) of the metal substrate. In this case, since the lower surface of the metal substrate can be made flat, the other members such as the cooler can be appropriately provided on the lower surface of the metal substrate. As a result, it is possible to make the heat radiation of the metal-based mounting board further excellent.

Further, for example, in the present invention, the grooves have only to be provided within at least the first region of the metal substrate, and therefore may be also provided within the second region in addition to the first region.

Furthermore, for example, the metal-based mounting board (the metal substrate) is of the plate shape in the above mentioned embodiment, but may be of a curved plate shape in the present invention.

In this regard, in the case where the metal-based mounting board is of the curved plate shape, the first region is defined based on a plurality of normal lines each passing through the surface of the electronic component facing the metal film. In this case, the plurality of lines each having the angle of 45° or less with respect to each normal line are set so as to pass through an intersection point of each normal line with the lower surface of the electronic component, respectively.

Furthermore, the metal-based mounting board is used by being bonded to the motor in the above mentioned embodiment, but may be used by being bonded to the other members or may be used without being bonded to the other members in the present invention.

Furthermore, for example, the number of the metal-based mounting board provided in the motor with board is three in the above mentioned embodiment, but is not limited thereto, and may be one, two or four or more.

Furthermore, for example, the motor is the SR motor in the above mentioned embodiment, but is not limited thereto, and may be a synchronous motor, an induction motor or a continuous current motor.

Furthermore, for example, the whole shape of the motor is the hexagonal columnar shape in the above mentioned embodiment, but is not limited thereto, and may be a square columnar shape, a pentagonal columnar shape or a cylindrical shape. Further, examples of the other shapes include a shape defined by flat surfaces and curved surfaces. Even if a member to which the metal-based mounting board is to be bonded has such a shape including the curved surfaces, since the metal-based mounting board has the grooves, it is possible to make shape followability thereof to the member excellent. This makes it possible to reliably obtain high adhesion between the member and the metal-based mounting board.

Furthermore, for example, the number of the metal-based mounting board provided on a single side surface of the housing of the motor is one in the above mentioned embodiment, but is not limited thereto, and may be two or more.

Furthermore, for example, the metal-based mounting boards are provided on the side surfaces of the housing of the motor in the above mentioned embodiment, but may be provided on an end surface (a surface on the opposite side of the shaft or a surface on the side of the shaft) of the housing.

Moreover, for example, the metal-based mounting board may have a function of controlling also operation that has to switch an actuator(s) other than the motor and the like.

What is claimed is:

1. A metal-based mounting board comprising:
a metal-based circuit board including a metal substrate having a first surface and a second surface opposite to the first surface, an insulating film provided on the first surface of the metal substrate and a metal film provided on the insulating film; and
an electronic component provided on the metal film of the metal-based circuit board,
wherein in the case where within the metal substrate, a region which overlaps with a collection of a plurality of lines each having an angle of 45° or less with respect to a normal line of the metal-based mounting board, the lines each passing through a surface of the electronic component facing the metal film, is defined as a first region, and a region other than the first region is defined as a second region, at least one groove is provided within the first region so as to surround the electronic component in a planar view of the metal-based mounting board.

2. The metal-based mounting board as claimed in claim 1, wherein the electronic component includes at least one type of an insulated gate bipolor transistor, a field effect transistor and a transformer.

3. The metal-based mounting board as claimed in claim 1, wherein the metal substrate is formed of aluminum or an aluminum alloy.

4. The metal-based mounting board as claimed in claim 1, wherein the groove is provided on the second surface of the metal substrate.

5. The metal-based mounting board as claimed in claim 1, wherein a width of the groove is in the range of 0.025 to 5 mm.

6. The metal-based mounting board as claimed in claim 1, wherein a depth of the groove is in the range of 0.10 to 5 mm.

7. The metal-based mounting board as claimed in claim 1, wherein a thickness of the metal substrate is in the range of 0.8 to 7.0 mm.

8. The metal-based mounting board as claimed in claim 1, wherein in the case where a depth of the groove is defined as D [mm] and a thickness of the metal substrate is defined as T [mm], D and T satisfy a relationship of 0.20≦D/T≦0.95.

9. The metal-based mounting board as claimed in claim 1, wherein a thickness of the metal film is in the range of 10 to 500 μm.

10. The metal-based mounting board as claimed in claim 1, wherein a thickness of the insulating film is in the range of 40 to 300 μm.

11. The metal-based mounting board as claimed in claim 1, wherein in the case where in the second surface of the metal substrate, an area occupied by the first region is defined as S₁ [mm²] and an area occupied by the second region is defined as S₂ [mm²], S₁ and S₂ satisfy a relationship of 0.50≦S₁/S₂≦4.0.

12. The metal-based mounting board as claimed in claim 1, wherein in the case where in the second surface of the metal substrate, an area occupied by the first region is defined as S₁ [mm²] and an area occupied by the groove is defined as S_{G} [mm²], S₁ and S_{G} satisfy a relationship of 0.03≦S_{G}/S₁≦0.70.

13. The metal-based mounting board as claimed in claim 1, wherein the at least one groove includes a plurality of the grooves intersecting with each other.

14. A member provided with metal-based mounting board comprising:
a cooler; and
the metal-based mounting board defined by claim 1 and provided on the cooler.

15. The member provided with metal-based mounting board as claimed in claim 14, wherein the cooler is a housing of a motor.
